(19) United States
(12) Patent Application Publication
(10) Pub. No.: US 2004/0099962 A1
(43) Pub. Date: May 27, 2004

(54) Flip chip electrical test yields by countering substrate die area coplanarity

(76) Inventors: Sarathy Rajagopalan, Milpitas, CA (US); Yogendra Ranade, Fremont, CA (US)

Correspondence Address: LSI LOGIC CORPORATION, 1621 BARBER LANE, MS: D-106 LEGAL, MILPITAS, CA, 95035, US

(21) Appl. No.: 10/302,470

(22) Filed: Nov. 22, 2002

(51) Int. Cl. H05K 1/11

(52) U.S. Cl. 257/786; 174/250; 174/257; 361/774

(57) ABSTRACT

A substrate which includes an upper and lower surface. The substrate also includes a center or interior portion and a peripheral portion. The upper surface is contoured at the center portion. Solder bumps extend from the upper surface and are positioned in the center portion, and solder bumps extend from the upper surface and are positioned in the peripheral portion. Additional solder material is added to the solder bumps. By adding the additional solder material to the solder bumps, a planar surface is provided by the upper surfaces of the center solder bumps and the peripheral solder bumps. Adding solder to the solder bumps in the periphery portion compensates for the die area planarity differences between the center portion and the periphery portion. As a result of adding solder, planarity issues between the die and the substrate are reduced. Thus, yield losses due to opens in the flipchip joints are also decreased.

### BACKGROUND

This invention generally relates to integrated circuit packaging and in particular flipchip packaging. Flipchip substrates have die planarity issues which result from a variety of reasons. One reason the planarity issues exist is because different vendors use different methods to process the substrates. As a result the die area planarity of the substrate varies from one vendor to another depending on the type of processing undertaken. For example, one flipchip substrate vendor laminates different buildup layers to manufacture the substrate. Another vendor prints a liquid to build up layers and cures it. Each method produces different profiles in the die area and hence different die area planarity.

Another factor which contributes to planarity issues is the size of the die. For example, the higher the die or a larger the area of the die, the more warpage or non-planarity will occur. In addition, a copper plane in the substrate under the die area also contributes to planarity issues.

These planarity issues create problems when attempting to join the die and the substrate. As shown in FIG. 1, a substrate 10, sometimes referred to as a “coined substrate”, is provided. The substrate 10 includes an upper surface 10a and a lower surface 10b. Coined solder portions 12 extend from the upper surface 10a of the substrate 10. A center portion 14 of the substrate 10 is surrounded by a peripheral portion 16 of the substrate 10. The upper surface 10a is contoured such that the height of the upper surface 10a is greater in the center portion 14 of the substrate 10 than it is at the peripheral portion 16.

A die 20 to be joined with the substrate 10 is shown in FIG. 2. The die 20 includes an upper surface 20a and a lower surface 20b. A center portion 22 of the die 20 is surrounded by a periphery portion 24. Bumps 30 of solder extend from the upper surface 20a of the die 20 and are provided on each contact pad to be joined with the substrate 10. The die 20 has been inverted (or “flipped”) to align the solder bumps 30 with the solder 12 of the substrate 10. Initially, as shown in FIG. 1, the solder 12 on the substrate 10 is planar. However, during reflow, as shown in FIG. 2, the solder portions 12 melt and form bumps which take the profile or contour of the substrate 10 and therefore become non-planar. The solder bumps 12 are higher in the center portion 14 of the substrate 10 than the solder bumps 12 in the peripheral portion 16 of the substrate 10. To properly join the die 20 to the substrate 10, the solder bumps 30 of the die 20 must coalesce with the solder 12 of the substrate 10.

As shown in FIG. 2, the non-planarity or warpage of the substrate solder bumps 12 often prevents the solder bumps 30 from the die 20 from coalescing with the solder bumps 12 of the substrate 10, resulting in opens (or non-wets) 36. The high warpage is especially at issue in the periphery portions 16, 24 of the substrate 10 the die 20.

Thus, there is a need for a substrate with improved planarity. In order to achieve high final electrical test yields, die area planarity must be as low as possible. The present invention aims to improve the electrical test yield losses which are caused by non-wet joints in Flipchip packaging.

### OBJECTS AND SUMMARY

It is an object of an embodiment of the present invention to decrease the planarity issues between the substrate and the die.

It is another object of an embodiment of the present invention to decrease the yield losses due to “opens” in flipchip joints.

Briefly, and in accordance with at least one of the foregoing objects, an embodiment of the present invention provides an increased amount of solder at the peripheral joints between the substrate and the die.

### BRIEF DESCRIPTION OF THE DRAWINGS

The present invention and the advantages thereof will become more apparent upon consideration of the following detailed description when taken in conjunction with the accompanying drawings of which:

FIG. 1 illustrates a cross sectional view of a coined substrate with solder on the contact pads;

FIG. 2 illustrates a cross sectional view of the joints of a prior art flip chip package;

FIG. 3 illustrates a cross-sectional view of an embodiment of a substrate including the solder arrangement of the present invention; and

FIG. 4 illustrates an embodiment of the method of the present invention.

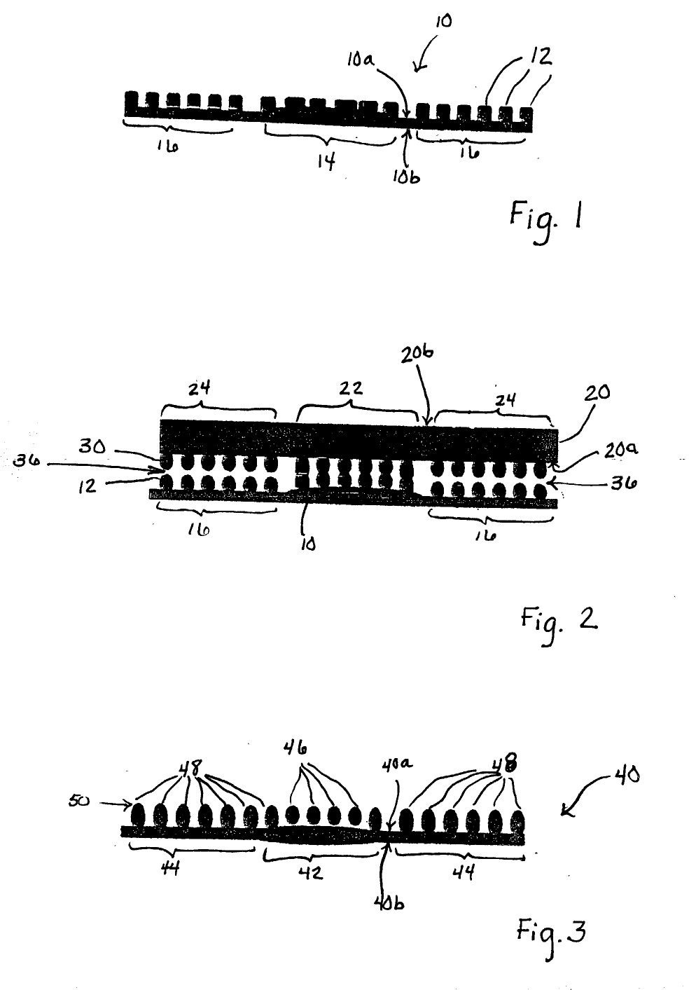

### DESCRIPTION

While the invention may be susceptible to embodiment in different forms, there is shown in the drawings, and herein will be described in detail, a specific embodiment with the understanding that the present disclosure is to be considered an exemplification of the principles of the present invention, and is not intended to limit the invention to that as illustrated and described herein.

A substrate 40 in accordance with an embodiment of the present invention is shown in FIG. 3. The substrate 40 includes an upper surface 40a and a lower surface 40b. The substrate 40 also includes a center or interior portion 42 and a peripheral portion 44 surrounding the center portion 42. The upper surface 40a of the substrate 40 is contoured at the center portion 42. Solder bumps 46 extend from the upper surface 40a of the substrate 40 and are positioned in the center portion 42 of the substrate 40. Solder bumps 48 extend from the upper surface 40a of the substrate 40 and are positioned in the peripheral portion 44 of the substrate 40. Additional solder material has been added to the solder bumps 48. By adding the additional solder material to the solder bumps 48, a planar surface 50 is provided by the upper surfaces of the center solder bumps 46 and the peripheral solder bumps 48. The amount of solder added to the peripheral solder bumps 48 will depend on the profile of the “die area” of the substrate 40. Adding solder to the solder bumps 48 in the periphery portion 44 of the substrate compensates for the die area planarity differences between the center portion 42 and the periphery portion 44 of the substrate 40. Adding solder to the solder bumps 48 during the molten stage allows the solder from the solder bump 30 to coalesce easily with the solder bump 48 from the substrate.

As a result of adding solder to the solder bumps 48, planarity issues between the die 20 and the substrate 40 are reduced. Thus, yield losses due to opens in the flipchip joints are also decreased.

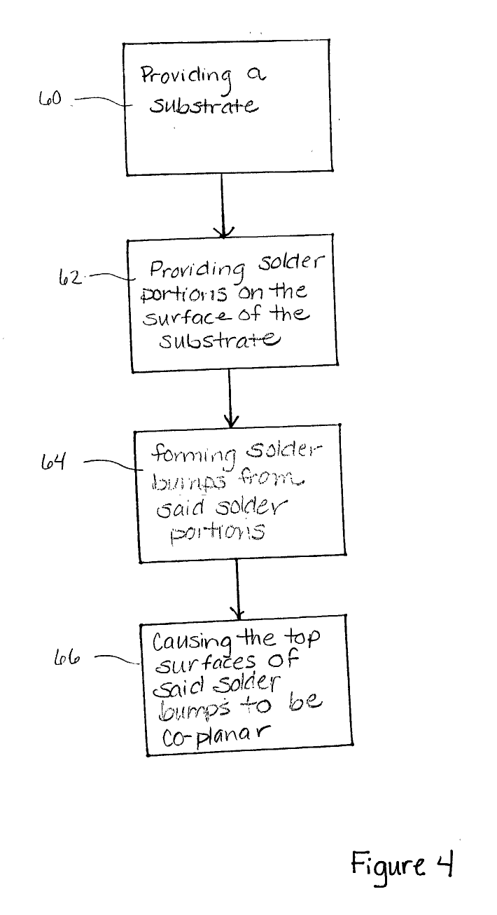

The method of forming a substrate to be joined with a flipchip die is represented in FIG. 4. The method begins by providing a substrate (represented by box 60). Next, solder portions are provided on the top surface of the substrate (represented by box 62). Preferably, these solder portions are provided in the interior portion and the peripheral portions of the die. The solder bumps are then formed (represented by box 64), preferably by reflow of the solder portions. Finally, the top surfaces of the solder bumps are caused to be co-planar (represented by box 66). Preferably, the top surfaces of the solder bumps are caused to be coplanar by providing additional solder on the solder bumps in the peripheral portion of the substrate such that the top surfaces of the solder bumps in the peripheral portion of the substrate are co-planar with the top surfaces of the solder bumps in the interior portion of the substrate.

While an embodiment of the present invention is shown and described, it is envisioned that those skilled in the art may devise various modifications of the present invention without departing from the spirit and scope of the appended claims.

What is claimed is:

1. A substrate comprising:
a bottom surface,
a top surface,
a plurality of solder bumps extending from said top surface, and
wherein the top surfaces of said solder bumps are planar.

2. A substrate as defined in claim 1, wherein said top surface comprises:
an interior portion, and
a peripheral portion surrounding said interior portion.

3. A substrate as defined in claim 2, wherein said plurality of solder bumps are disposed in said interior portion and said peripheral portion.

4. A substrate as defined in claim 2, wherein said plurality of solder bumps disposed within said peripheral portion are larger than said solder bumps disposed in said interior portion.

5. A method of making a substrate to be joined with a flipchip die including the steps of:
providing a substrate having a top surface and a bottom surface,
providing a plurality of solder portions extending from said top surface of said substrate,
forming solder bumps from said plurality of solder portions, and
adding solder to a number of said plurality of solder bumps such that the top surfaces of said plurality of solder portions create a planar surface.

6. A method as defined in claim 5, further including the step of:
providing a substrate, wherein said top surface of said substrate comprises an interior portion and a peripheral portion surrounding said interior portion.

7. A method as defined in claim 6, further including the step of:
providing a substrate, wherein said plurality of solder bumps are disposed in said interior portion and said peripheral portion.

8. A method as defined in claim 6, wherein said step of adding solder comprises adding solder to said solder bumps in said peripheral portion.
